(19) United States
(12) Patent Application Publication
(10) Pub. No.: US 2011/0201143 A1
(43) Pub. Date: Aug. 18, 2011

(54) METHOD FOR MANUFACTURING A THIN FILM SOLAR CELL MODULE

(75) Inventors: Per-Oskar Westin, Uppsala (SE); Uwe Zimmermann, Uppsala (SE); Marta Ruth, Dubendorf (CH)

(73) Assignee: SOLIBRO RESEARCH AB, Uppsala (SE)

(21) Appl. No.: 13/123,949

(22) PCT Filed: Oct. 13, 2009
(86) PCT No.: PCT/SE09/51167

§ 371 Date: Apr. 13, 2011

(30) Foreign Application Priority Data
Oct. 13, 2008 (SE) 0850035-7

(51) Int. Cl. H01L 31/18

(52) U.S. Cl. 438/66; 257/E31.124

(57) ABSTRACT

A method for manufacturing a thin film solar cell module including at least a first and a second thin film solar cell, includes the steps of forming a first and a second back contact on a substrate. The active CIGS layer, or the absorber layer, and a window layer that extends over the first and the second back contacts is then deposited in a vacuum equipment. To form solar cells electrically isolated from each other, a first portion of the absorber layer and the window layer is separated from a second portion of the absorber layer the window layer. To connect the thin film solar cells in series, an electrical interconnection between the first portion of the window layer and the second back contact is formed by selectively transforming a third portion of the absorber layer to an electrically conductive compound.

### TECHNICAL FIELD OF THE INVENTION

The present invention relates to the manufacturing of thin film solar cell modules and in particular electrical contacting of such solar cells.

### BACKGROUND OF THE INVENTION

In addition to today's dominant solar cell technology based on crystalline silicon, thin film solar cells have been developed. They offer the potential for substantial cost reductions due to their reduced consumption of materials and energy in comparison to crystalline silicon solar cells but have, in general, lower conversion efficiencies and are less durable. A very promising thin film solar cell technology which is based on a semiconductor CIGS layer has demonstrated high efficiencies and durability in operation. However, it remains to demonstrate it can be produced commercially at a low cost. CIGS is an abbreviation for the typical alloying elements, i.e. Cu, In, Ga, Se and S, in the semiconductor materials which are used to form Cu(In₁₋ₓGaₓ)Se₂ compounds. Commonly the CIGS layer also comprises sulphur, i.e. Cu(In₁₋ₓGaₓ)(Se_{1-y}S_{y})₂.

A typical CIGS-based thin film solar cell comprises a substrate, made of glass or metal foil that is covered with a back contact layer, an absorber layer and a window layer. By way of example the layers of the thin film solar cell may be formed by depositing a back contact layer made of Mo on the substrate, growing a CIGS absorber layer, forming a window layer comprising a buffer layer made of CdS and a front contact made of a transparent conductive oxide such as Al-doped ZnO (“ZAO”). A high resistivity thin layer made of ZnO may be provided between the buffer layer and the front contact. Cd-free buffer layers, for example made of ZnO_{z}Si_{1-z}, are also becoming available. Such thin film solar cells are usually electrically connected in series to form a thin film solar cell module.

A prior art method for manufacturing of such a thin film solar cell module is described in the following with reference to FIG. 1 showing a device indicating the result of the different steps. A substrate such as a sheet of glass or a metal foil is provided with a back contact layer, typically made of Mo, which is subjected to a first patterning step (P1) to form longitudinal segments of the back contact layer. An in-line production apparatus is used to deposit a CIGS layer by high vacuum co-evaporation of the alloying elements of the CIGS layer. A buffer layer, typically 50 nm of CdS, and a high resistivity thin layer of ZnO (sometimes omitted or sometimes added after a second patterning step (P2) described next) are then deposited onto the CIGS layer. Thereafter the semiconductor layers, i.e. the CIGS layer, the buffer layer and the high resistivity layer, are subjected to a second patterning step (P2) to form longitudinal segments in parallel to and overlapping the longitudinal segments of the back contact layer. According to this prior art method the second patterning step comprises mechanical scribing using a mechanical stylus. A front contact layer of a transparent conductive oxide, e.g. of Al-doped ZnO, is deposited on the top surface of the segmented semiconductor layers. The front contact and the underlying semiconductor layers are finally subjected to a third patterning step (P3) to define and separate the serially connected longitudinal thin film solar cell segments of the thin film solar cell module. Also in the third patterning step (P3) mechanical scribing is performed using a mechanical stylus.

The accuracy and cleanliness of the mechanical scribing used to make an electrical contact between the back contact layer and the front contact layer is critical for the performance and long term stability of the final thin film solar cell module. Residuals, such as debris, from the scribing may degrade the electrical and optical properties in the back contact/absorber and absorber/front contact interfaces, respectively. Wear of the stylus may cause varying scribe widths and thus varying sizes of the individual thin film solar cells. In addition a worn stylus may also cause damage in the underlying layers. Furthermore it has been concluded that the direct contact between the back contact layer and the window layer may be a limiting factor for the long term stability of the thin film solar cell module. Consequently these problems also limit both the efficiency of the solar cell module as well as the manufacturing yield. Mechanical scribing also has some inherent drawbacks related to the throughput. The patterning of the semiconductor layers has to be made with accurate alignment to the longitudinal segments of the back contact layer, and subsequently the patterning to form thin film solar cell segments has to be aligned to these two patterning steps.

Moreover, the thin film deposition, which is a vacuum process, has to be interrupted for the second patterning step (P2).

Referring to FIG. 2B, partial laser ablation of CIGS-layers to provide a monolithic electrical interconnect between the front contact layer and the back contact layer in thin film solar cells on flexible substrates has been disclosed as an alternative to mechanical scribing shown in FIG. 2A. The reason for using laser ablation instead of mechanical scribing in this case is that the flexible substrates are not rigid enough, or are too rough, to allow mechanical scribing. In the second patterning step (P2) of such a prior art method a portion of the CIGS material is transformed to an electrically conductive compound by partial ablation, i.e. laser scribing, of the CIGS layer. Thereafter the other layers are deposited on top of the CIGS layer and the transformed portion of the CIGS layer provides the electrical contact between the back contact and the window layers. Furthermore, scribing, photolithography and etching or laser ablation have been used in a third patterning step (P3) to define and separate neighbouring thin film solar cells on flexible substrates which cannot tolerate mechanical scribing with a stylus. Regardless of which mentioned prior art method is used, the scribing results in debris polluting the surface of the absorber layer, therefore possibly the interface between the absorber layer and the window layer, and degrades its performance. Thus cleaning of the module between process steps allocates a substantial part of the total process time.

### SUMMARY OF THE INVENTION

The prior art has drawbacks with regards to being able to provide a scribing operation that fulfils the requirements of high volume production.

The objective of the present invention is to overcome some of the drawbacks of the prior art. This is achieved by the method as defined in the independent claims.

One method according to the invention comprises the steps of forming a back contact layer on a substrate, forming an absorber layer that extends over the back contact layer, forming a window layer that covers the absorber layer, and subsequently transforming a portion of the absorber layer to an electrically conductive compound by irradiating said portion of the absorber layer with a laser beam.

One embodiment of a method for manufacturing a thin film solar cell module comprising at least a first and a second thin film solar cell electrically connected in series, in accordance with the present invention, comprises the step of forming a first and a second back contact on a substrate, wherein the first back contact is associated with the first thin film solar cell and the second back contact is associated with the second thin film solar cell. The active CIGS layer, or absorber layer, and a window layer that extend over the first and the second back contact may then be deposited in a vacuum equipment without breaking the vacuum between the deposition steps. To form isolated solar cells electrically isolated from each other, a first portion of the absorber layer and a first portion of the window layer is separated from a second portion of the absorber layer and a second portion of the window layer wherein said first portions are associated with the first thin film solar cell and said second portions are associated with the second thin film solar cell. In order to connect the thin film solar cells in series, an electrical interconnection between the first portion of the window layer and the second back contact is formed by selectively transforming a third portion of the absorber layer to an electrically conductive compound by irradiating said third portion with a laser beam.

Thanks to the invention, it is not only possible to decrease the process time, but also to significantly increase the cleanliness of the process as it makes it possible to avoid defect formation in the interface between the absorber layer and the window layer, since the surface of the absorber layer does not have to be exposed during scribing. In addition, it is possible to provide a thin film solar cell module without breaking the vacuum between the deposition of the absorber layer and the deposition of the window layer.

It is a also an advantage of the invention to provide the possibility to further increase the efficiency and decrease the total process time, since the separation of the absorber layer and the window layer of the first and the second thin film solar cell can be made substantially simultaneously with the laser treatment to form the electrical interconnection between the back contact of the first cell and the window layer of the second cell.

Embodiments of the invention are defined in the dependent claims. Other objects, advantages and novel features of the invention will become apparent from the following detailed description of the invention when considered in conjunction with the accompanying drawings and claims.

### BRIEF DESCRIPTION OF THE DRAWINGS

Preferred embodiments of the invention will now be described with reference to the accompanying drawings, wherein:

FIG. 1 shows a schematic prior art solar cell comprising mechanically scribed trenches.

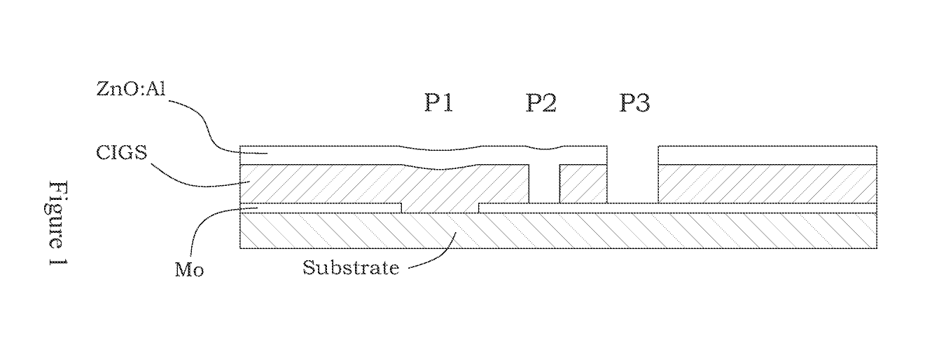

FIG. 2 illustrates the difference between a) prior art mechanical scribing and b) prior art laser scribing.

FIG. 3 shows a schematic of solar cells connected in series.

FIG. 4 shows schematically methods according to the invention.

FIG. 5 shows schematically the formation of the electrical interconnection in a sequence a-b-c, done by, a) depositing the layers, b) isolating the cells from each other by isolating the window layer and absorber layer of the first solar cell from the window layer and absorber layer of the second solar cell, and c) forming the electrical interconnection through the window layer, where the electrical interconnection is formed after isolating the cells from each other.

FIG. 6 shows schematically the formation of the electrical interconnection in a sequence a-b-c, done by a) depositing the layers, b) forming the electrical interconnection through the window layer, and c) isolating the cells from each other by isolating the window layer and absorber layer of the first solar cell from the window layer and absorber layer of the second solar cell, where the electrical interconnection is formed before isolating the cells from each other.

FIG. 7 shows schematically the formation of the electrical interconnection in a sequence a-b-c, done by a) depositing the layers, b) isolating the cells from each other by isolating the window layer of the first solar cell from the window layer of the second solar cell and c) forming the electrical interconnection through the window layer, where the electrical interconnection is formed after isolating the cells from each other.

FIG. 8 shows schematically the formation of the electrical interconnection in a sequence a-b-c, done by a) depositing the layers, b) forming the electrical interconnection through the window layer, and c) isolating the cells from each other by isolating the window layer of the first solar cell from the window layer of the second solar cell, where the electrical interconnection is formed before isolating the cells from each other.

FIG. 9 shows a current-voltage plot exhibiting a current-voltage characteristics for one module formed by a prior art method, and one module formed by a method of the invention.

### DETAILED DESCRIPTION OF EMBODIMENTS

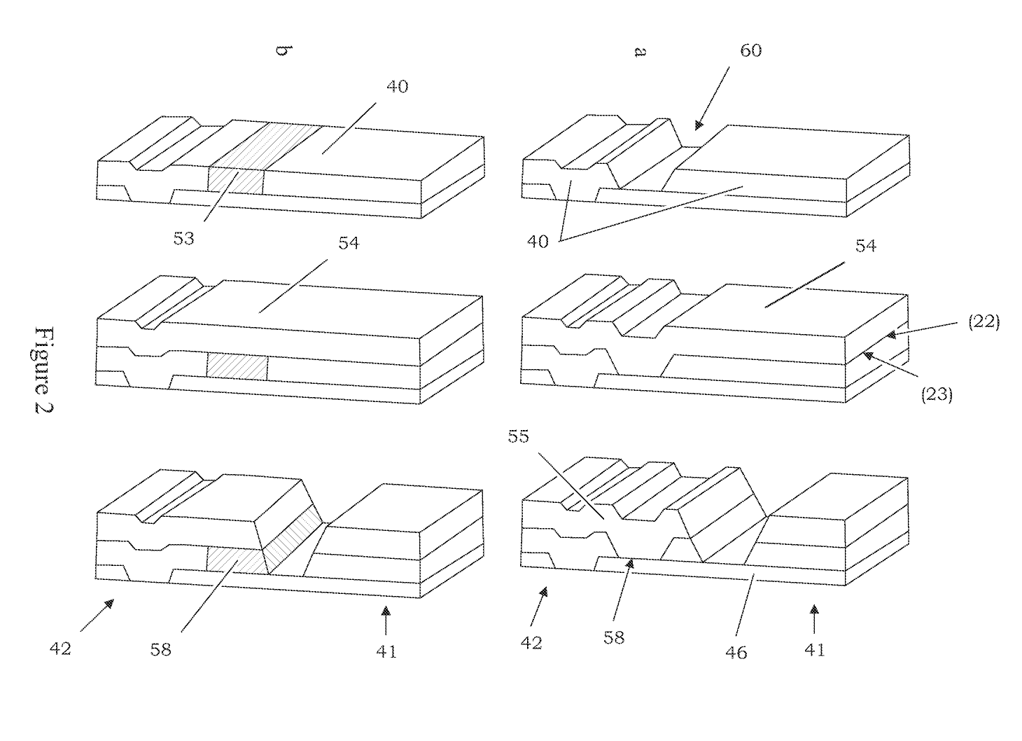

Referring to FIG. 2 in a thin film solar cell according to prior art, as described above, the electrical interconnect 58 between a back contact 46 of one thin film solar cell 41 and the window layer 55 of an adjacent thin film solar cell 42 is made immediately after the deposition of the absorber layer 40. This can be done in two alternative ways: either the absorber layer is removed, shown in FIG. 2a, in order to form an absorber trench 60, where the window layer 54 can reach and be electrically connected to the back contact 46, and subsequently, the solar cells 41,42 must be isolated from each other by employing for example mechanical scribing; or it is also possible, as shown in FIG. 2b to transform a portion 53 of the absorber layer 40 after deposition to make it electrically conducting using a laser stimulated phase transformation method, and then, subsequently depositing the window layer 54 and executing the mechanical scribing to isolate the solar cells 41,42 from each other.

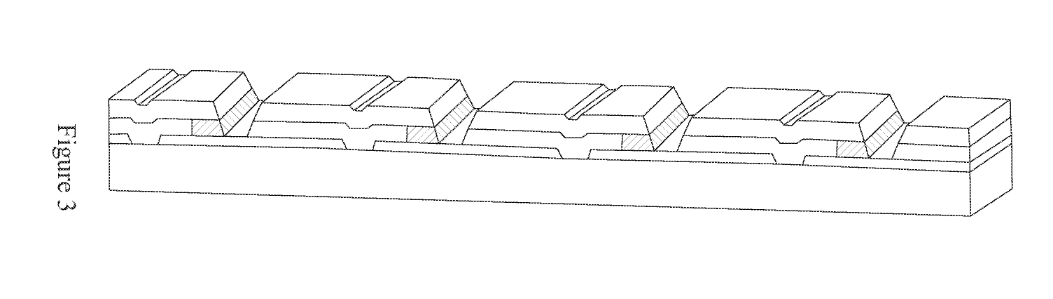

A thin film solar cell module according to the present invention comprises at least a first and a second thin film solar cell 1, 2, although it may comprise several solar cells as seen in FIG. 3. The solar cells within the module are electrically connected in series. Although the following description describes a module comprising two solar cells it is appreciated by a person skilled in the art that there is no restriction in the number of thin film solar cells in a thin film solar cell module. The number of cells that are serially connected determines the theoretical output voltage of the module.

The substrate used when manufacturing thin film solar cells can be a semiconductor substrate like for example a silicon wafer, which often is used to make bulk solar cells. But to be competitive in price, and to large extent increase flexibility, another alternative is glass or soda-lime-glass substrates. However, when making thin film solar cells in accordance with the present invention, a special substrate is not required, thus virtually any substrate may be used depending on the final application.

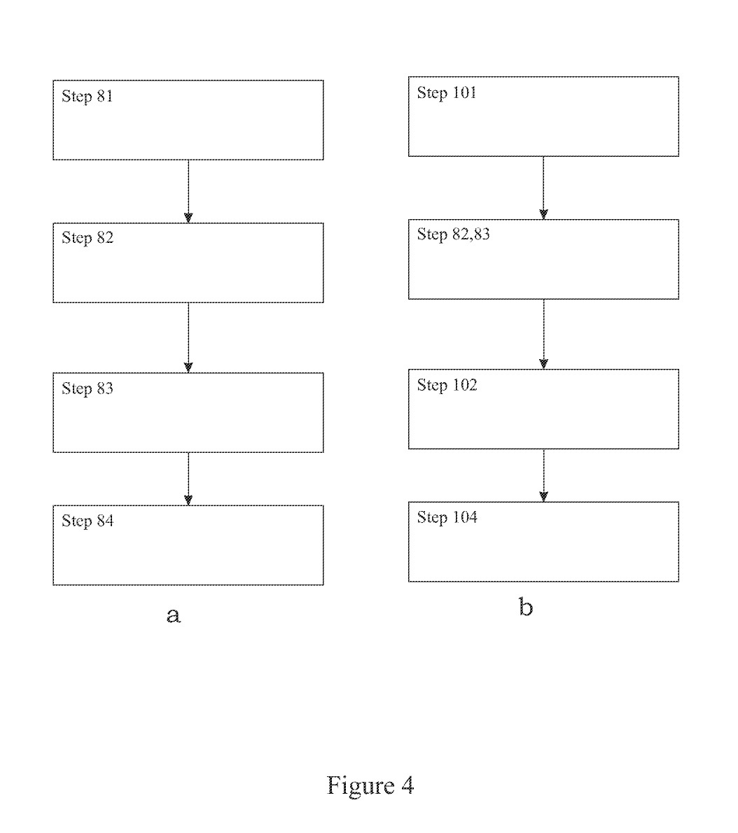

In one embodiment of the present invention, referred to in FIG. 4a, a method for manufacturing a thin film solar cell comprises the steps of;
81 forming a back contact layer on a substrate,
82 forming an absorber layer covering the back contact layer,
83 forming a window layer covering the absorber layer, and then
84 transforming a portion of the absorber layer to an electrically conductive compound by irradiating said portion of the absorber layer with a laser beam.

Referring to FIG. 4b, another embodiment of a method for manufacturing a thin film solar cell module comprising at least a first and a second thin film solar cell 1, 2 electrically connected in series according to the present invention comprises the steps of:
101 forming a first and a second back contact 5,6 on a substrate 4, wherein the first back contact 5 is associated with the first thin film solar cell 1 and the second back contact 6 is associated with the second thin film solar cell 2;
82 forming an absorber layer covering the back contact layer,
83 forming a window layer covering the absorber layer,
the absorber layer 10 extends over the first and the second back contacts 5,6;

said method further comprising the steps of:
102 electrically isolating a first portion 15 of the window layer 14 from a second portion 16 of the window layer 14 wherein said first portions 15 is associated with the first thin film solar cell 1 and said second portions 16 is associated with the second thin film solar cell 2; and
104 forming an electrical interconnection 18 between the first portion 15 of the window layer 14 and the second back contact 6 by selectively transforming a third portion 13 of the absorber layer 10 to an electrically conductive compound by irradiating said third portion 13 with a laser beam.

The order in which the process steps in FIG. 4a and FIG. 4b are performed is just an example, and not meant to be a restriction.

In one embodiment of the method for manufacturing a thin film solar cell module the step 102 electrically isolating further comprises the step 103 electrically separating a first portion 11 of the absorber layer 10 from a second portion 12 of the absorber layer 10, wherein said first portion 11 is associated with the first thin film solar cell 1 and said second portion 12 is associated with the second thin film solar cell 2;

When fabricating a thin film solar cell module, a back contact layer is typically deposited on the substrate in order to form the back contacts. The back contact layer often comprises a layer of molybdenum (Mo), even though other metals, conductive compounds or multiple layers may be used instead or as well. The back contact layer can be deposited using for example physical vapour deposition techniques (PVD) like sputtering or evaporation. When choosing the back contact material there is a trade-off between the optical reflectivity and the electrical properties of the material. Mo does not have the best optical reflectivity of the possible metals, nor the best conductivity. Nevertheless, it is currently still the preferred choice when the absorber layer is CIGS, since it forms a good ohmic contact for holes (majority carriers) towards CIGS meanwhile it exhibits a low recombination for electrons (minority carriers). This favours the performance of each solar cell, thus the performance of the solar cell module.

In one embodiment of the present invention the back contact is initially deposited to cover substantially the entire module. Subsequently, the first back contact 5 and the second back contact 6 are electrically isolated from each other, for example by employing laser scribing. Also conventional semiconductor processing techniques like for example photo-lithography and etching are possible methods for forming the separation between back contacts.

On top of the back contacts 5, 6 an absorber layer that extends over both the first 5 and the second 6 back contacts is deposited. In the case where the absorber layer is CIGS, deposition of the latter is a complex process, and one way of doing it is by co-evaporation using multiple sources as described in WO2005086238. On top of the absorber layer 10, a window layer 14 is formed using a standard deposition technique like for example sputtering. The window layer 14 serves as the top contact for each individual solar cell. In one embodiment of the present invention, the absorber layer is a semiconducting CIGS layer, but in other conceivable embodiments of the present invention the absorber layer does not necessarily comprise CIGS. It can be any layer capable of generating charge carriers when exposed to light emission, for example a-Si or CdTe.

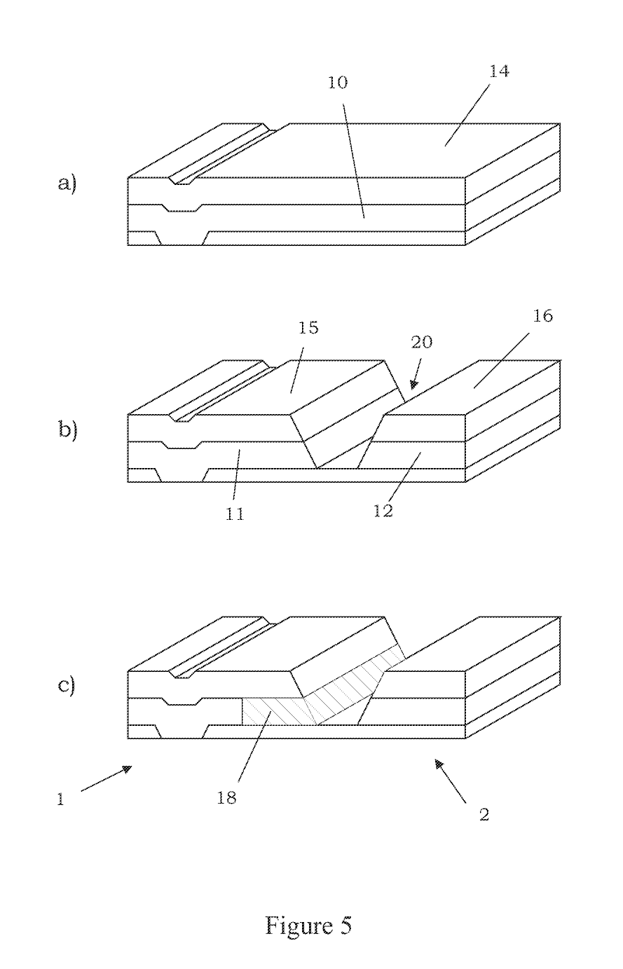

In one embodiment according to the invention, a first portion 15 of the window layer 14 is isolated from a second portion 16 of the window layer 14 and a first portion 11 of the absorber layer 10 is isolated from a second portion 12 of the absorber layer 10 by forming a trench 20. The trench 20 may be formed by mechanical scribing, as shown in FIG. 5, but also other methods like photo-lithography, laser ablation or laser stimulated material transformation may be used. Laser stimulated material transformation is a method where the material undergoes a material transformation upon irradiation with a beam from a laser, owing to the energy supplied during irradiation. Thus, instead of removing the material when forming the trench 20 in FIG. 5, the material may be transformed into an electrically insulating compound, that also electrically separates the first thin film solar cell 1 from the second thin film solar cell 2. One thing that requires close attention associated with this method is that it is difficult to avoid forming a conducting bypass of a melted and subsequently solidified absorber layer phase, which ruins the function of the device. Energy supplying sources other than a laser may be used to supply energy to the portion of material intended to be transformed. The electrical interconnection 18 can thereafter be formed to connect the first thin film solar cell 1 and the second thin film solar cell 2 to each other. The electrical connection 18 can also be formed prior to or simultaneously as the formation of the trench 20. The trench 20 may also be formed to extend only through the window layer 14, thus it separates only the two portions 15,16 of the window layer 14 from each other.

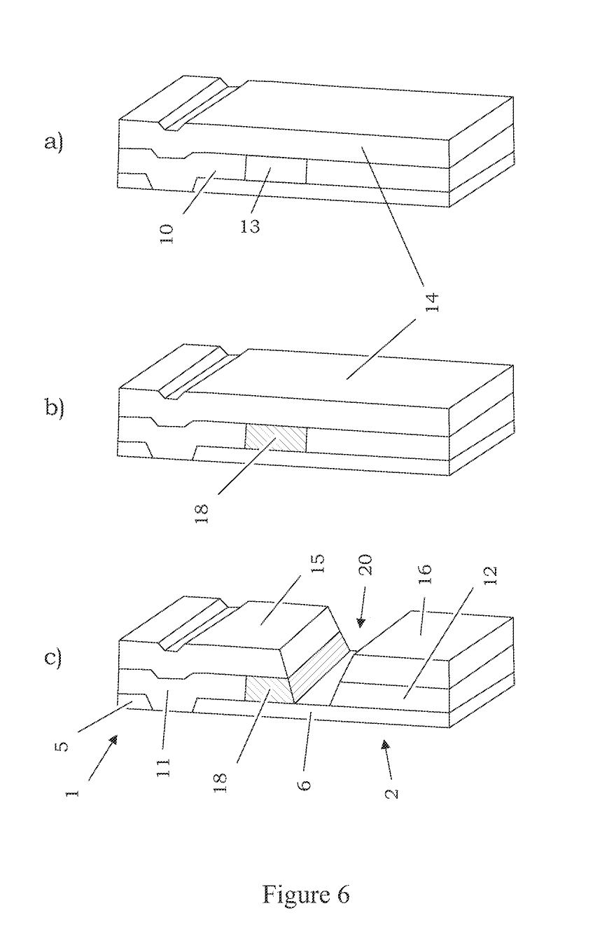

As the first thin film solar cell 1 and the second thin film solar cell 2 are formed and separated, the top contact, i.e. the first window layer 15 needs to be in electrical contact with the second back contact 6 for the solar cells to be connected in series as illustrated in FIG. 3. In one embodiment according to the invention, this is done by selectively transforming a third portion 13 of the absorber layer 10 by forming an electrically conductive compound between the first portion 15 of the window layer 14 and the second back contact 6 illustrated in FIG. 6 This can be achieved by irradiating said third portion 13 with a laser beam, that is, by using laser stimulated material transformation. Thus, an electrical interconnect 18 between the first portion 15 of the window layer 14 and the second back 6 contact is formed. This step of forming the electrical interconnect 18 can also be done prior to the step of separating the first thin film solar cell 1 from the second thin film solar cell 2. Independent of at which stage this is performed, this method brings a lot of advantages as compared to the prior art.

In particular, the cleanliness is significantly improved. Debris from the mechanical or laser scribing has been shown to decrease performance of thin film solar cells, as it can be responsible for the formation of defects within the device, predominantly in the interface between the window layer 14 and the absorber layer 10. Encapsulating the latter by the window layer before mechanical or laser scribing completely erases this problem, since the interface between the two said layers may never be exposed to the ambient atmosphere during mechanical or laser scribing. In addition, process time and pollutions in the window-/absorber-layer interface possibly causing degradation may further be reduced by performing the deposition or growth steps in the same vacuum chamber without breaking the vacuum, since in that case the latter does not need to be opened between depositions, which is possible with the method of the present invention. Not breaking the vacuum means that the environment in the chamber is not in open contact with the normal atmosphere outside the vacuum chamber, but only with the controlled atmosphere inside the vacuum chamber. A vacuum chamber can be for example a deposition chamber where it is possible to accurately control the local environment. Thus, for example, temperature, gases and gas flows, partial pressure of gases etc. can be individually controlled. Several vacuum chambers can be connected to form a vacuum system, where the substrates can be transferred between vacuum chambers within the system without being exposed to normal atmosphere.

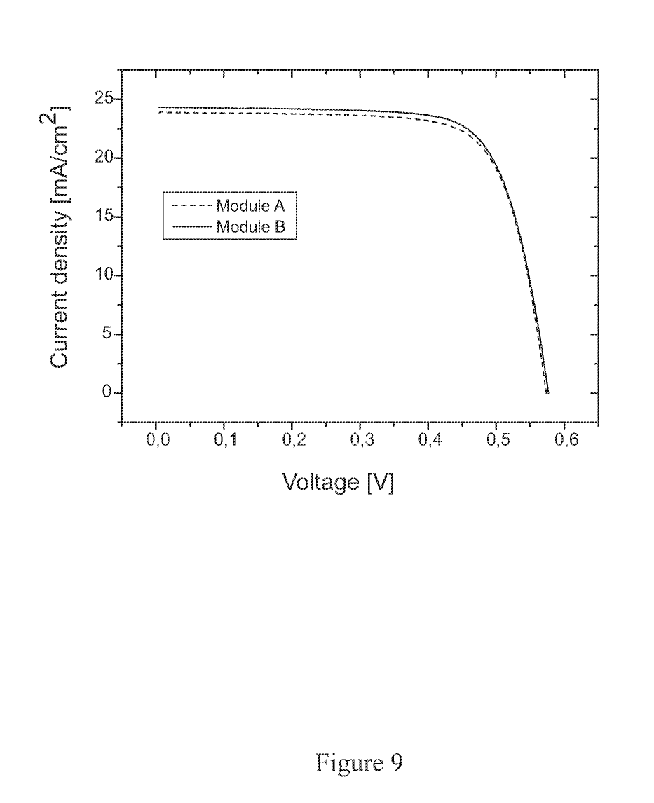

The performance of the solar cell modules as produced by methods of the invention is seen in FIG. 9 which shows experimental data exhibiting a current-voltage characteristics for two modules. The modules A and B were processed in parallel except for the steps significant for the invention. Thus, A has been manufactured according to a state of the art method and B that has been manufactured according to a method according to the invention. Deposition of the CIGS-layer was done using in-line co-evaporation of the constituents on a Mo-coated soda lime glass. The buffer layer was deposited by chemical bath deposition (CBD) subsequently followed by deposition of the resistive layer using sputtering. Processing of the prior art module was followed by, in sequence, mechanical interconnect patterning “P2”—Sputter deposition of window layer—Mechanical isolation patterning “P3”, whereas processing of the module according to the invention was followed by, in sequence, sputter deposition of the window layer—Mechanical isolation patterning “P3”—Interconnect patterning using laser patterning through the window layer. The modules were then again processed in parallel in order to provide a module for testing. Solar cell characteristics was measured for solar cell module B to be efficiency: 10.31%, fill factor (FF): 73%, open circuit voltage (V_{oc}): 577 mV, short-circuit current (J_{sc}): 24.3 mA. In addition, from FIG. 9 it is clear that the modules exhibit equivalent performance.

Although the modules perform equally well, the method of the invention brings a lot of advantages as compared to the prior art. The scribing can be performed with the sensitive absorber layer capped under the window layer 14 protecting the sensitive interface in between. Thus, thorough and time consuming cleaning of the absorber layer 10 surface after scribing, before further processing, is not a necessity. Another advantage of the embodiments of the invention, as compared to prior art, is that by performing the deposition steps immediately after each other in one and the same vacuum chamber without removing the substrate from said chamber in between depositions, the processing time is drastically reduced.

In one embodiment according to the invention, the step of isolating the first portion 15 of the window layer 14 from the second portion 16 of the window layer 14 and the first portion 11 of the absorber layer 10 from a second portion 12 of the absorber layer 10 is made substantially simultaneously with the step of creating an electrical interconnection 18 between the first portion 15 of the window layer and the second back contact 6. This can be done by using, for example, an XY-table equipped with a combined mechanical scriber and a laser, for respectively scribing the trench 20 and transforming the material to form the electrical interconnect 18. Performing these steps simultaneously further reduces the process time. If not done simultaneously, the order in which these steps are performed can be altered.

In one embodiment according to the invention, shown in FIG. 5 the step of isolating the first portion 15 of the window layer 14 from the second portion 16 of the window layer 14 and isolating the first portion 11 of the absorber layer 10 from a second portion 12 of the absorber layer 10 is done simultaneously (go directly from a to c in FIG. 5) or prior to (follow the sequence a-b-c in FIG. 5) the formation of the electrical interconnection 18. The latter can be placed adjacent to the trench 20. The step of isolating the first portion 15 of the window layer 14 from the second portion 16 of the window layer 14 and isolating the first portion 11 of the absorber layer 10 from a second portion 12 of the absorber layer 10 may also be done after the formation of the electrical interconnection 18, as illustrated by the sequence a-b-c in FIG. 6.

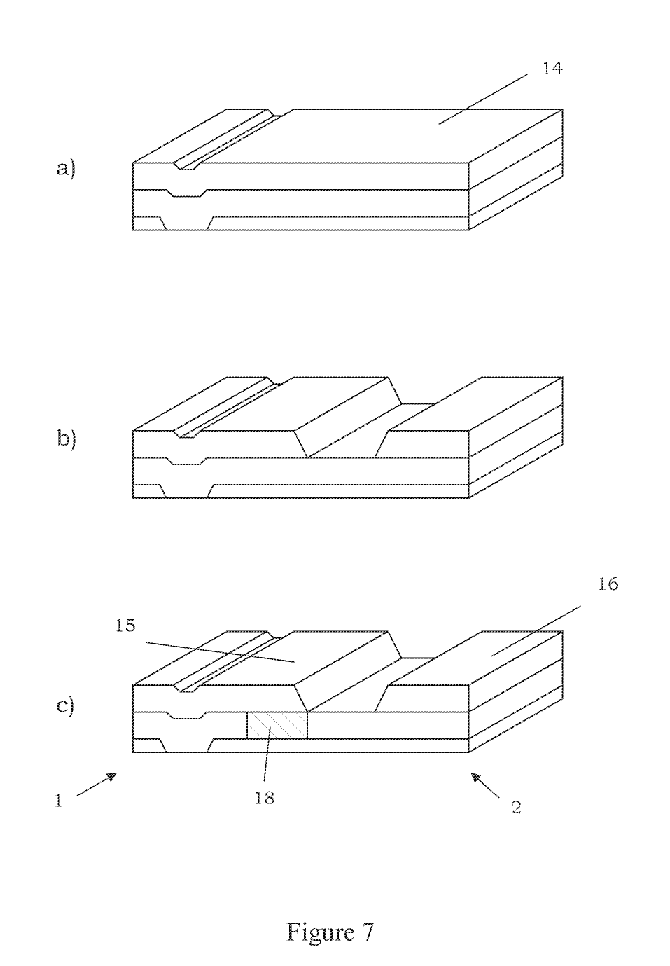

In one embodiment according to the invention, shown in FIG. 7, the isolation of the first thin film solar cell 1 from the second thin film solar cell 2 is done by isolating the first portion 15 of the window layer 14 from the second portion 16 of the window layer 14, subsequently followed by the step of forming an electrical interconnection 18. These steps may also be performed simultaneously.

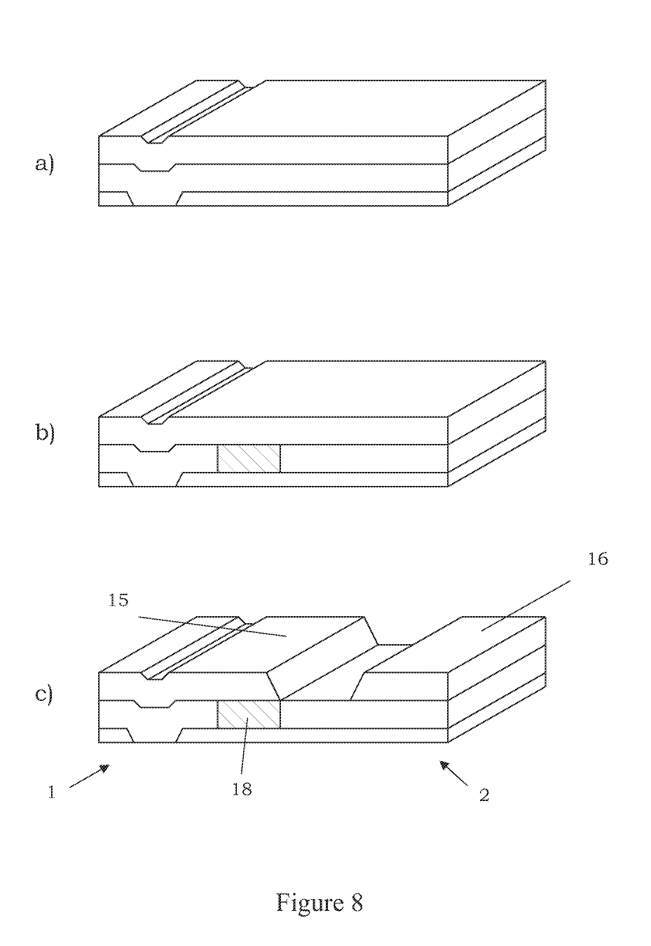

In one embodiment according to the invention, shown in FIG. 8, the isolation of the first thin film solar cell 1 from the second thin film solar cell 2 is done by isolating the first portion 15 of the window layer 14 from the second portion 16 of the window layer 14, prior to the step of forming an electrical interconnection 18. These steps may also be performed simultaneously.

In one embodiment of a method of manufacturing a thin film solar cell module, the method further comprises the step of depositing a buffer layer 22, for example in between the steps of depositing an absorber layer 10 and a window layer 14.

In another embodiment of a method of manufacturing a thin film solar cell module, the method further comprises the step of depositing a high resistivity layer 23, for example in between the steps of depositing an absorber layer 10 and a window layer 14.

Thin film solar cells of CIGS-type may be designed in such way that the contact adjacent to the substrate should be called the “front contact” instead of the “back contact” as described above, since the thin film solar cell device may be built so that the light is incident through the substrate instead of through the contact on the opposite side of the structure. The present invention is described for a thin film solar cell device wherein the light is incident from the absorber-side, i.e. with the back contact between the substrate and the absorber layer, however not limited to this design.

The figures are not to scale and, for the sake of clarity of illustration, the relative dimensions are not always accurate, e.g. some layers are shown as being too thin relative to others.

In addition, the materials of the layered structure of the thin film solar cell device, i.e. the back contact layer, the buffer layer, and the high resistivity layer may, as a person skilled in the art appreciate, be replaced by other materials or combination of materials for example; Mo can be replaced by other refractory metals like Nb, Ta, W Ti etc. or refractory nitrides like TiN, ZrN, HfN etc, CIGS can be replaced by other variants in the CIGS+S system like CuInS₂, Cu(InGa)S₂, Cu(InGa)(S,Se)₂, CuInSn(S,Se), Kesterites etc, and the Al doped ZnO can be replaced by ITO, Ga doped ZnO or B doped ZnO. Further, additional layers may be added to the layered structure, for example buffer layers, antireflective layers, back-reflector layers.

While the invention has been described in connection with what is presently considered to be the most practical and preferred embodiments, it is to be understood that the invention is not to be limited to the disclosed embodiments, on the contrary, is intended to cover various modifications and equivalent arrangements which are within the scope of the appended claims.

1-12. (canceled)

13. A method for manufacturing a thin film solar cell module comprising the steps of:
(81) forming a back contact layer (7) on a substrate (4);
(82) forming an absorber layer (10) that extends over the back contact layer (7);
(83) forming a window layer (14) that covers the absorber layer (10);
(84) transforming a portion of the absorber layer (10) to an electrically conductive compound by irradiating said portion of the absorber layer (10) with a laser beam.

14. The method for manufacturing a thin film solar cell module according to claim 13 wherein the steps of:
(82) forming an absorber layer (10);
(83) forming a window layer (14); and
the further step of, in between the steps of forming an absorber layer (10) and a window layer (14), depositing a buffer layer (22) and a high resistivity layer (23);
where the steps of (82) forming an absorber layer (10), (83) forming a window layer (14), depositing a buffer layer (22) and depositing a high resistivity layer (23) onto the substrate (4) are performed within one vacuum system.

15. The method for manufacturing a thin film solar cell module according to claim 13 comprising at least a first and a second thin film solar cell (1, 2) electrically connected in series wherein:
the step of (81) forming a back contact layer (7) further comprising the step of (101) forming a first and a second back contact (5, 6) on a substrate (4), wherein the first back contact (5) is associated with the first thin film solar cell (1) and the second back contact (6) is associated with the second thin film solar cell (2); said method further comprising the steps of:
(102) electrically isolating a first portion (15) of the window layer (14) from a second portion (16) of the window layer (14), wherein said first portion (15) is associated with the first thin film solar cell (1) and said second portion (16) is associated with the second thin film solar cell (2); and
(104) forming an electrical interconnection (18) between the first portion (15) of the window layer (14) and the second back contact (6) by selectively transforming a third portion (13) of the absorber layer (10) to an electrically conductive compound by irradiating said third portion (13) with a laser beam.

16. The method for manufacturing a thin film solar cell module according to claim 14, wherein the step of (102) electrically isolating further comprises the step of (103) electrically separating a first portion (11) of the absorber layer (10) from a second portion (12) of the absorber layer (10), wherein said first portion (11) is associated with the first thin film solar cell (1) and said second portion (12) is associated with the second thin film solar cell (2).

17. The method for manufacturing a thin film solar cell module according to claim 15, wherein the step of (104) forming an electrical interconnection (18) is made subsequent to the step of (102) electrically isolating.

18. The method for manufacturing a thin film solar cell module according to claim 15, wherein the step of (104) forming an electrical interconnection (18) is made prior to the step of (102) electrically isolating.

19. The method for manufacturing a thin film solar cell module according to claim 15, wherein the step of (102) electrically isolating comprises the step of (103′) forming a trench (20) extending through the window layer (14) or extending through the window layer (14) and the absorber layer (10).

20. The method for manufacturing a thin film solar cell module according to claim 19, wherein the third portion (13) of the absorber layer (10) is adjacent to the trench (20).

21. The method for manufacturing a thin film solar cell module according to claim 19, wherein the step of (103′) forming a trench (20) comprises mechanical scribing.

22. The method for manufacturing a thin film solar cell module according to claim 19, wherein the step of (103′) forming a trench (20) comprises laser scribing.

23. The method for manufacturing a thin film solar cell module according to claim 15, wherein the step of (102) electrically isolating and the step of (104) forming an electrical interconnection (18) is made substantially simultaneously.

24. The method for manufacturing a thin film solar cell module according to claim 13, wherein the absorber layer (10) is a semiconducting CIGS layer.

25. The method for manufacturing a thin film solar cell module according to claim 14 comprising at least a first and a second thin film solar cell (1, 2) electrically connected in series wherein:
the step of (81) forming a back contact layer (7) further comprising the step of (101) forming a first and a second back contact (5, 6) on a substrate (4), wherein the first back contact (5) is associated with the first thin film solar cell (1) and the second back contact (6) is associated with the second thin film solar cell (2); said method further comprising the steps of:
(102) electrically isolating a first portion (15) of the window layer (14) from a second portion (16) of the window layer (14), wherein said first portion (15) is associated with the first thin film solar cell (1) and said second portion (16) is associated with the second thin film solar cell (2); and
(104) forming an electrical interconnection (18) between the first portion (15) of the window layer (14) and the second back contact (6) by selectively transforming a third portion (13) of the absorber layer (10) to an electrically conductive compound by irradiating said third portion (13) with a laser beam.

26. The method for manufacturing a thin film solar cell module according to claim 15, wherein the step of (102) electrically isolating further comprises the step of (103) electrically separating a first portion (11) of the absorber layer (10) from a second portion (12) of the absorber layer (10), wherein said first portion (11) is associated with the first thin film solar cell (1) and said second portion (12) is associated with the second thin film solar cell (2).

27. The method for manufacturing a thin film solar cell module according to claim 16, wherein the step of (104) forming an electrical interconnection (18) is made subsequent to the step of (102) electrically isolating.

28. The method for manufacturing a thin film solar cell module according to claim 16, wherein the step of (104) forming an electrical interconnection (18) is made prior to the step of (102) electrically isolating.

29. The method for manufacturing a thin film solar cell module according to claim 20, wherein the step of (103′) forming a trench (20) comprises mechanical scribing.

30. The method for manufacturing a thin film solar cell module according to claim 20, wherein the step of (103′) forming a trench (20) comprises laser scribing.
